(19) United States
(12) Patent Application Publication
(10) Pub. No.: US 2017/0012143 A1
(43) Pub. Date: Jan. 12, 2017

(54) SEMICONDUCTOR DEVICE AND METHOD OF MANUFACTURING THE SAME

(71) Applicant: Renesas Electronics Corporation, Tokyo (JP)

(72) Inventors: Tatsuya USAMI, Ibaraki (JP); Takashi OGURA, Ibaraki (JP)

(21) Appl. No.: 15/186,521

(22) Filed: Jun. 19, 2016

(30) Foreign Application Priority Data
Jul. 7, 2015 (JP) 2015-136331

(51) Int. Cl. H01L 31/0288; H01L 31/0352; H01L 31/18

(52) U.S. Cl. CPC H01L 31/0288; H01L 31/1804; H01L 31/035281

(57) ABSTRACT

A germanium optical receiver in which a dark current is small is achieved. The germanium optical receiver is formed of a p-type germanium layer, a non-doped i-type germanium layer, and an n-type germanium layer that are sequentially stacked on an upper surface of a p-type silicon core layer, a first cap layer made of silicon is formed on the side surface of the i-type germanium layer, and a second cap layer made of silicon is formed on the upper surface and side surface of the n-type germanium layer. The n-type germanium layer is doped with such an element as phosphorus or boron having a covalent bonding radius smaller than a covalent bonding radius of germanium.

### CROSS-REFERENCE TO RELATED APPLICATION

The present application claims priority from Japanese Patent Application No. 2015-136331 filed on Jul. 7, 2015, the content of which is hereby incorporated by reference into this application.

### TECHNICAL FIELD OF THE INVENTION

The present invention relates to a semiconductor device and a technique of manufacturing the same, and can be preferably used for, for example, a semiconductor device in which a germanium optical receiver (photodetector) is embedded and for manufacturing the semiconductor device.

### BACKGROUND OF THE INVENTION

Japanese Patent Application Laid-Open Publication No. H10-290023 (Patent Document 1) describes a semiconductor photodetector having an n-type germanium layer, a germanium single-crystal layer, a p-type germanium layer, and a p-type silicon layer formed in a trench whose side wall is covered with a silicon oxide film and which is formed in an n-type silicon layer, the semiconductor photodetector using the germanium single-crystal layer as a light-absorbing layer.

J. Fujikata et al., “High Performance Silicon Waveguide-Integrated PIN and Schottky Ge Photodiodes and their Link with Inverter-Type CMOS TIA Circuits” (Non-Patent Document 1, J. Fujikata, M. Noguchi, M. Miura, D. Okamoto, T. Horikawa, and Y. Arakawa, “High Performance Silicon Waveguide-Integrated PIN and Schottky Ge Photodiodes and their Link with Inverter-Type CMOS TIA Circuits”, Extended Abstracts of the 2013 International Conference on Solid State Devices and Materials, Fukuoka, 2013, pp 980 to 981) describes an optical receiver having a pin Ge diode structure and a schottky Ge diode structure formed of a p⁺-type silicon layer formed on a silicon substrate via a BOX layer, a germanium layer formed on the p⁺-type silicon layer, and an n⁺-type silicon germanium layer (or non-doped silicon germanium layer) formed on the germanium layer.

### SUMMARY OF THE INVENTION

In a silicon photonics technique, an optical receiver is an essential element for combining an optical circuit and an electronic circuit together, and therefore, a germanium optical receiver using a germanium semiconductor has a high potential. However, the germanium optical receiver has a problem in which a defect occurs on the interface between a silicon layer and a germanium layer due to a difference in a covalent bonding radius or damage caused by ion implantation, which results in increase in a dark current (that is a flowing current in spite of no light irradiation).

The other object and novel characteristics of the present invention will be apparent from the description of the present specification and the accompanying drawings.

A semiconductor device according to one embodiment includes: a silicon core layer; a p-type germanium layer formed on the upper surface of the silicon core layer; a non-doped i-type germanium layer formed on the upper surface of the p-type germanium layer; an n-type germanium layer formed on the upper surface of the i-type germanium layer; and a cap layer made of silicon and formed on the upper surface of the n-type germanium layer. To the n-type germanium layer, an element having a covalent bonding radius smaller than a covalent bonding radius of germanium is introduced.

A method of manufacturing the semiconductor device according to one embodiment includes: a step of forming a p-type germanium layer on the upper surface of a silicon core layer; a step of forming a non-doped i-type germanium layer on the upper surface of the p-type germanium layer; a step of forming a first cap layer made of silicon on the upper surface and side surface of the i-type germanium layer; and a step of forming a first insulating film so as to cover the first cap layer. Subsequently, the method also includes: a step of forming an opening reaching the i-type germanium layer by processing the first cap layer on the upper surface of the i-type germanium layer and the first insulating film; a step of forming an n-type germanium layer on the upper surface of i-type germanium layer that is exposed from the bottom surface of the opening; and a step of forming a second cap layer made of silicon on the upper surface and side surface of the n-type germanium layer. Subsequently, the method further includes: a step of forming a second insulating film so as to cover the second cap layer; a step of forming a connection reaching the second cap layer by processing the second insulating film on the upper surface of the second cap layer; and a step of forming a conductive material inside the connection. Here, the p-type germanium layer, i-type germanium layer, and first cap layer are formed continuously in the same device by an epitaxial growth method, and the n-type germanium layer and second cap layer are formed continuously in the same device by the epitaxial growth method. An impurity element introduced into the n-type germanium layer has a covalent bonding radius smaller than a covalent bonding radius of germanium.

According to one embodiment, a germanium optical receiver having a small dark current can be achieved.

### BRIEF DESCRIPTIONS OF THE DRAWINGS

FIGS. 1A and 1B are a top view of a principle part of a germanium optical receiver according to a first embodiment, and a cross-sectional view of the principle part of the germanium optical receiver (cross-sectional view taken along a line A-A of FIG. 1A), respectively;

FIGS. 2A and 2B are a top view of a principle part showing a manufacturing process of the germanium optical receiver according to the first embodiment, and a cross-sectional view of the principle part showing the manufacturing process (cross-sectional view taken along a line A-A of FIG. 2A), respectively;

FIGS. 3A and 3B are a top view of a principle part showing a manufacturing process of the germanium optical receiver, and a cross-sectional view of the principle part showing the manufacturing process, continued from FIG. 2, respectively;

FIGS. 4A and 4B are a top view of a principle part showing a manufacturing process of the germanium optical receiver, and a cross-sectional view of the principle part showing the manufacturing process, continued from FIG. 3, respectively;

FIGS. 5A and 5B are a top view of a principle part showing a manufacturing process of the germanium optical receiver, and a cross-sectional view of the principle part showing the manufacturing process, continued from FIG. 4, respectively;

FIGS. 6A and 6B are a top view of a principle part showing a manufacturing process of the germanium optical receiver, and a cross-sectional view of the principle part showing the manufacturing process, continued from FIG. 5, respectively;

FIGS. 7A and 7B are a top view of a principle part showing a manufacturing process of the germanium optical receiver, and a cross-sectional view of the principle part showing the manufacturing process, continued from FIG. 6, respectively;

FIGS. 8A and 8B are a top view of a principle part showing a manufacturing process of the germanium optical receiver, and a cross-sectional view of the principle part showing the manufacturing process, continued from FIG. 7, respectively;

FIGS. 9A and 9B are a top view of a principle part showing a manufacturing process of the germanium optical receiver, and a cross-sectional view of the principle part showing the manufacturing process, continued from FIG. 8, respectively;

FIGS. 10A and 10B are a top view of a principle part of a germanium optical receiver according to a second embodiment, and a cross-sectional view of the principle part of the germanium optical receiver (cross-sectional view taken along a line B-B of FIG. 10A), respectively;

FIGS. 11A and 11B are a top view of a principle part of a modification example of the germanium optical receiver according to the second embodiment, and a cross-sectional view of the principle part of the modification example of the germanium optical receiver (cross-sectional view taken along a line B-B of FIG. 11A), respectively;

FIGS. 12A and 12B are a top view of a principle part of a germanium optical receiver according to a third embodiment, and a cross-sectional view of the principle part of the germanium optical receiver (cross-sectional view taken along a line C-C of FIG. 12A), respectively;

FIGS. 13A and 13B are a top view of a principle part showing a manufacturing process of the germanium optical receiver according to the third embodiment, and a cross-sectional view of the principle part showing the manufacturing process (cross-sectional view taken along a line C-C of FIG. 13A), respectively;

FIGS. 14A and 14B are a top view of a principle part showing a manufacturing process of the germanium optical receiver, and a cross-sectional view of the principle part showing the manufacturing process, continued from FIG. 13, respectively;

FIGS. 15A and 15B are a top view of a principle part showing a manufacturing process of the germanium optical receiver, and a cross-sectional view of the principle part showing the manufacturing process, continued from FIG. 14, respectively; and

FIGS. 16A and 16B are a top view of a principle part showing a manufacturing process of the germanium optical receiver, and a cross-sectional view of the principle part showing the manufacturing process, continued from FIG. 15, respectively.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle.

Also, when “formed of A”, “formed by A”, “having A”, or “including A” is described, it goes without saying that other components are not eliminated unless otherwise specified to be only the component. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Also, components having the same function are denoted by the same reference symbols throughout all the drawings for describing the embodiments, and the repetitive description thereof is omitted. Hereinafter, the present embodiments are described in detail based on the drawings.

In recent years, the so-called silicon photonics technique has been actively developed, which is a technique of achieving an optical communication module by manufacturing an optical signal transmission line made of silicon as a material and integrating various optical devices and electronic devices using an optical circuit made up of the optical signal transmission line as a platform.

In an optical circuit based on an optical waveguide formed on a substrate made of silicon (Si), a silicon waveguide using a core made of silicon (Si) is mainly used. Silicon (Si) is a material widely used for electronic circuits, and usage of a silicon waveguide allows an optical circuit and an electronic circuit to be manufactured on the same substrate.

Incidentally, an optical receiver is essential for converting an optical signal into an electric signal, and usage of germanium (Ge) having a band gap narrower than that of Silicon (Si) has a high potential for the optical receiver. This is because usage of germanium (Ge) having a band gap narrower than that of Silicon (Si) is preferable rather than Si for detecting the near-infrared rays having a wavelength not larger than about 1.6 μm which is a communication wavelength band on an electronic circuit, and because germanium (Ge) has high affinity with Silicon (Si) and therefore can be formed to be monolithic on a silicon waveguide.

For example, an optical receiver having a pin structure formed of a p⁺-type silicon layer, a germanium layer, and an n⁺-type silicon germanium layer is proposed (e.g., Non-Patent Document 1). However, in the optical receiver having such a structure, there is a concern of increase in the dark current. That is, Silicon (Si) has a covalent bonding radius of 1.11 Å, and germanium (Ge) has a covalent bonding radius of 1.22 Å. Phosphorus (P) has a covalent bonding radius of 1.06 Å, and boron (B) has a covalent bonding radius of 0.82 Å.

Therefore, the covalent bonding radius of the p⁺-type silicon layer introduced with boron (B) is smaller than 1.11 Å, and therefore, a difference in a covalent bonding radius between the p⁺-type silicon layer and the germanium layer is larger than a difference in a covalent bonding radius between a non-doped silicon layer and the germanium layer. The same goes for the n⁺-type silicon germanium layer. As a result, a defect on the interface between the p⁺-type silicon layer and the germanium layer and on the interface between the n⁺-type silicon germanium layer and the germanium layer grows larger, and the increase in the dark current is assumed.

By applying an ion implantation method when an impurity is introduced into the silicon layer or germanium layer, a defect occurs on the interface between the silicon layer and the germanium layer due to the damage caused in the ion implantation, and the increase in the dark current is assumed.

The large dark current in the optical receiver causes determination error of the receiver. Therefore, it is important to reduce such a dark current in order to improve the performance and reliability of a semiconductor device.

Meanwhile, an optical receiver having a pin structure formed of an n-type germanium layer, a germanium single-crystal layer, and a p-type germanium layer that are formed continuously inside a trench by an epitaxial growth method is proposed (e.g., Patent Document 1). By this structure, the above-described increase in the dark current caused by the difference in the covalent bonding radius and the ion implantation method can be suppressed. However, if a space is formed between these layers and the side wall of the trench, there is a risk in which the n-type germanium layer and the p-type germanium layer approach each other, which results in interdiffusion of doping elements between both layers, and there is a possibility of deterioration of the functions of the optical receiver.

In the present embodiment, a structure of a germanium optical receiver capable of reducing a dark current and a method of manufacturing the germanium optical receiver are main features, and the details and effects of the structure and method will be clearly described in the following explanations.

### First Embodiment

<Structure of Semiconductor Device>

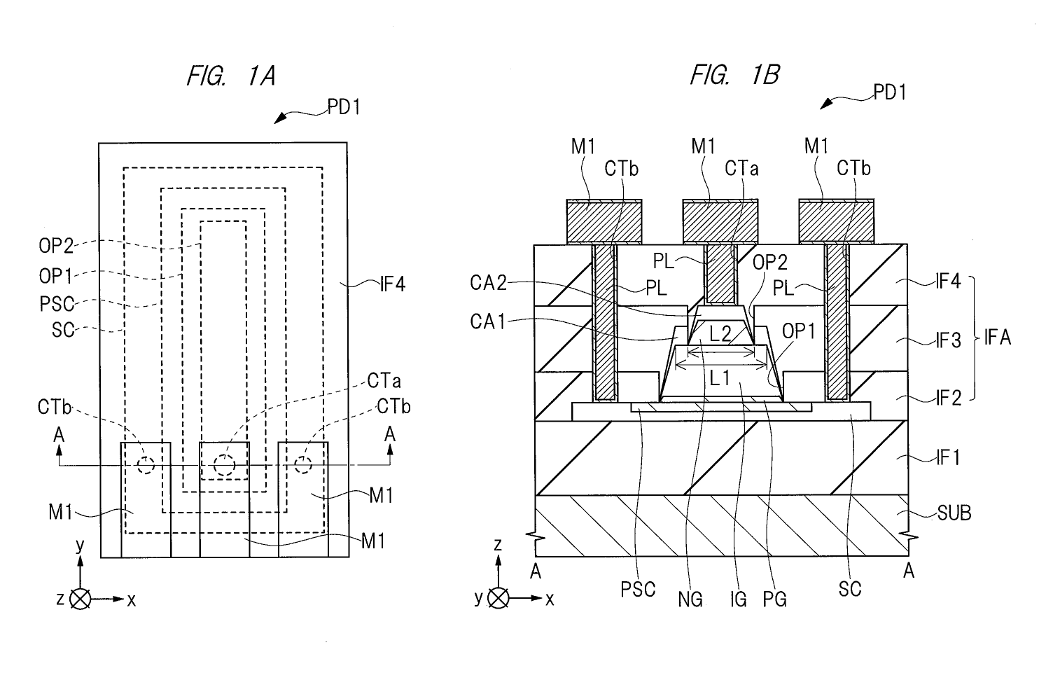

A structure of a germanium optical receiver according to a first embodiment will be described with reference to FIG. 1. FIGS. 1A and 1B are a top view of a principle part of the germanium optical receiver according to the first embodiment, and a cross-sectional view of the principle part of the germanium optical receiver (i.e., cross-sectional view taken along a line A-A of FIG. 1A), respectively.

The germanium optical receiver PD1 according to the first embodiment is formed of a p-type germanium layer PG introduced with a p-type impurity, a non-doped i-type (intrinsic type) germanium layer IG, and an n-type germanium layer NG introduced with an n-type impurity, which are sequentially stacked on the upper surface of a p-type silicon core layer PSC formed in a silicon core layer SC. Further, a first cap layer CA1 made of silicon (Si) is formed so as to cover the side surface of the i-type germanium layer IG, and a second cap layer CA2 made of silicon (Si) is formed so as to cover the upper surface and side surface of the n-type germanium layer NG.

Hereinafter, the configuration of the germanium optical receiver PD1 will be specifically described. The silicon core layer SC made of silicon (Si) is formed on a semiconductor substrate SUB made of single-crystal silicon (Si), via a first insulating film (referred also to as BOX layer or lower clad layer) IF1. A thickness of the first insulating film IF1 is, for example, 1 μm or more, preferably, about 2 μm to 3 μm. A suitable range of a thickness of the silicon core layer SC is considered to be, for example, from 100 nm to 300 nm (although this is obviously not limited to this range depending on other conditions). However, a thickness range in which 200 nm is a center value is considered to be the most preferable.

On a part of the surface of the silicon core layer SC, the p-type silicon core layer PSC introduced with a p-type impurity such as boron (B) by an ion implantation method is formed to be in contact with the p-type germanium layer PG. The impurity concentration of the p-type silicon core layer PSC is, for example, in a range of 10¹⁵ cm⁻³ to 10²⁰ cm⁻³, and is typically, for example, about 10¹⁸ cm⁻³.

The p-type germanium layer PG is formed on the upper surface of the p-type silicon core layer PSC, the i-type germanium layer IG is formed on the upper surface of the p-type germanium layer PG, and the n-type germanium layer NG is formed on the upper surface of the i-type germanium layer IG. That is, a vertical pin structure is formed of the p-type germanium layer PG, the i-type germanium layer IG, and the n-type germanium layer NG.

The p-type germanium layer PG is the germanium layer introduced with a p-type impurity such as boron (B), and has a thickness of, for example, 100 nm or less. The i-type germanium layer IG has a thickness of, for example, about 300 nm to 20,000 nm. The n-type germanium layer NG is the germanium layer introduced with an n-type impurity such as phosphorus (p), and has a thickness of, for example, about 100 nm to 200 nm.

Each cross-sectional shape of the p-type germanium layer PG, the i-type germanium layer IG, and the n-type germanium layer NG is substantially trapezoidal, and the n-type germanium layer NG is formed so that the width L2 of the lower surface of the n-type germanium layer NG in the x direction is smaller than the width L1 of the upper surface of the i-type germanium layer IG in the x direction. Similarly, the n-type germanium layer NG is formed so that the width of the lower surface of the n-type germanium layer NG in the y direction is smaller than the width of the upper surface of the i-type germanium layer IG in the y direction.

The side surface of the p-type germanium layer PG, a part of the upper surface of the i-type germanium layer IG (the part of the upper surface where the n-type germanium layer NG is not formed), and the side surface of the i-type germanium layer IG are covered with the first cap layer CA1 made of silicon (Si).

The upper surface and side surface of the n-type germanium layer NG are covered with the second cap layer CA2 made of silicon (Si).

The peripheries of the first and second cap layers CA1 and CA2 are covered with an insulating film (referred also to as upper clad layer) IFA. The insulating film IFA is formed of a second insulating film IF2, a third insulating film IF3, and a fourth insulating film IF4, each of which is made of silicon oxide (SiO₂). The insulating film IFA has a thickness of, for example, about 2 μm to 3 μm.

In the insulating film IFA, a connection hole CTb reaching the silicon core layer SC is formed. In the fourth insulating film IF4, a connection hole CTa reaching the second cap layer CA2 is formed. A plug (referred also to as buried electrode or buried contact) PL mainly made of tungsten (W) used together with a barrier metal as a main conductive material is formed inside the connection holes CTa and CTb. The barrier metal is provided for preventing the diffusion of the metal serving as the main conductive material making up the plug PL, and is made of, for example, titanium (Ti), titanium nitride (TiN), or others. This thickness is, for example, about 5 nm to 20 nm.

On the insulating film IFA, a first layer wiring M1 is formed. The first layer wiring M1 is formed of a main conductive material made of, for example, aluminum (Al), copper (Cu), or aluminum-copper alloy (Al—Cu alloy), and a barrier metal formed on the lower and upper surfaces of the main conductive material. The barrier metal is provided for preventing the diffusion of the metal serving as the main conductive material making up the first layer wiring M1, and is made of, for example, tantalum (Ta), titanium (Ti), tantalum nitride (TaN), titanium nitride (TiN), or others. This thickness is, for example, about 5 nm to 20 nm. In the first embodiment, the germanium optical receiver PD1 having the wiring with the single-layer structure is exemplified. However, the germanium optical receiver is not limited to this, and the germanium optical receiver may have a multiple-layer wiring formed of two or more layers. Alternatively, a copper (Cu) Damascene structure may be used.

In the germanium optical receiver PD1 of the present first embodiment, the p-type germanium layer PG, the i-type germanium layer IG, the n-type germanium layer NG, and the second cap layer CA2 made of silicon are sequentially formed on the p-type silicon core layer PSC. As described above, the covalent bonding radius of silicon is (Si) is 1.11 Å, and the covalent bonding radius of germanium (Ge) is 1.22 Å. Also, the covalent bonding radius of phosphorus (P) is 1.06 Å, and the covalent bonding radius of Boron (B) is 0.82 Å.

Therefore, the n-type germanium layer NG introduced with phosphorus (P) is formed between the i-type germanium layer IG and the second cap layer CA2, so that the occurrence of the defect on respective interfaces among those layers is suppressed because the i-type germanium layer IG, the n-type germanium layer NG, and the second cap layer CA2 become gradually smaller in the covalent bonding radius in this order, and therefore, the increase in the dark current can be suppressed.

Similarly, the p-type germanium layer PG introduced with Boron (B) is formed between the i-type germanium layer IG and the p-type silicon core layer PSC, so that the occurrence of the defect on respective interfaces among those layers is suppressed because the i-type germanium layer IG, the p-type germanium layer PG, and the p-type silicon core layer PSC become gradually smaller in the covalent bonding radius in this order, and therefore, the increase in the dark current can be suppressed.

In the germanium optical receiver PD1 according to the present first embodiment, note that the p-type germanium layer PG is formed on the silicon core layer SC side, and the i-type germanium layer IG and n-type germanium layer NG are sequentially formed on the p-type germanium layer PG. However, the n-type germanium layer NG may be formed on the silicon core layer SC side, and the i-type germanium layer IG and p-type germanium layer PG may be sequentially formed on the n-type germanium layer NG. Since the first layer wiring M1 is formed so that the first layer wiring M1 overlaps a partial region of the germanium optical receiver PD1 when seen in a plan view, the p-type germanium layer PG can receive light even when the p-type germanium layer PG is formed as an upper layer and the n-type germanium layer NG is formed as a lower layer.

Here, the germanium optical receiver whose plane pattern is rectangular has been described. However, an optical receiver having a circular pattern may be applicable. In the case of the rectangular pattern, a pattern whose one side is several μm and the other side is several tens of μm is typically used. In the case of the circular pattern, a diameter of several tens of μm to several hundreds of μm is used.

<Method of Manufacturing Semiconductor Device>

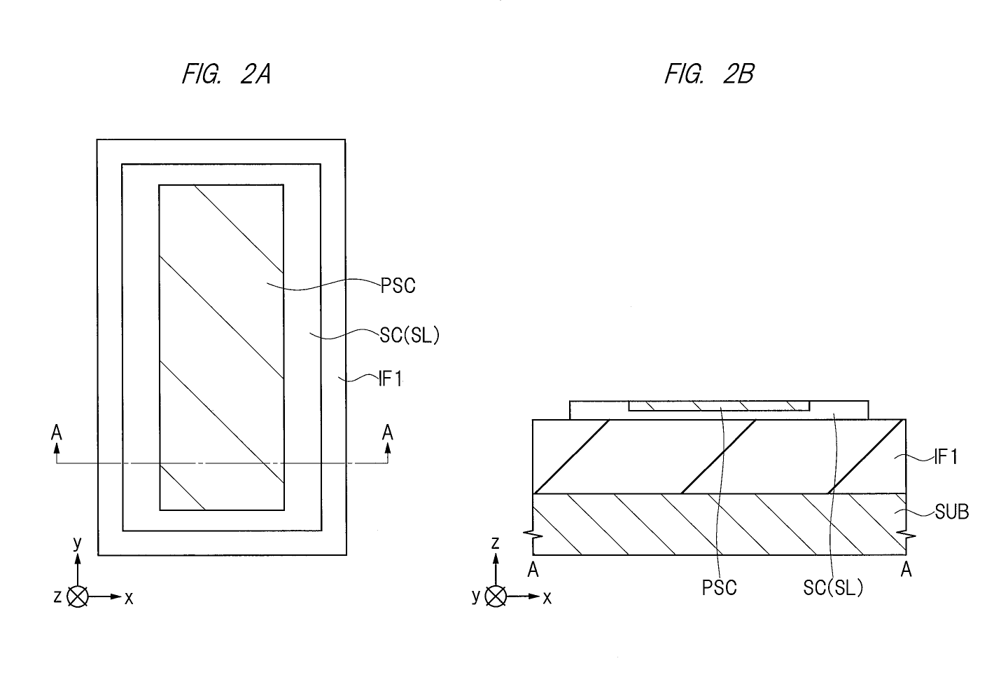

A method of manufacturing the germanium optical receiver according to the present first embodiment will be described in order of processes with reference to FIGS. 2 to 9. In FIGS. 2 to 9, FIGS. 2A to 9A show top views of a principle part of the germanium optical receiver during manufacturing processes of the present first embodiment, and FIGS. 2B to 9B show cross-sectional views of the principle part of the germanium optical receiver (i.e., cross-sectional views taken along a line A-A of each of FIGS. 2A to 9A), respectively.

As shown in FIGS. 2A and 2B, an SOI (Silicon On Insulator) substrate (which is a substrate having substantially a planar circular shape referred to as SOI wafer in this stage) is prepared first, the SOI substrate being made of the semiconductor substrate SUB, the first insulating film IF1 formed on the main surface of the semiconductor substrate SUB, and a silicon layer (referred also to as SOI layer) formed on the first insulating film IF1.

The semiconductor substrate SUB is a support substrate made of single-crystal silicon (Si), and the first insulating film IF1 is made of silicon oxide (SiO₂). A thickness of the first insulating film IF1 is, for example, 1 μm or more, preferably about 2 μm to 3 μm. A thickness of the silicon layer SL is, for example, about 100 nm to 300 nm, preferably about 200 nm.

Then, a resist pattern (illustration is omitted) is formed by coating the silicon layer SL with a photoresist, exposing the layer to light, and then, performing a development process to pattern the photoresist. Subsequently, a silicon core layer SC is formed by processing the silicon layer SL by dry etching while using the resist pattern as a mask. Then, the resist pattern is removed.

Then, in order to obtain the contact between the silicon core layer SC and the p-type germanium layer PG formed on a main surface of the silicon core layer SC, a p-type impurity, such as boron (B), is introduced into a part of the surface of the silicon core layer SC by an ion implantation method to form the p-type silicon core layer PSC. The impurity concentration of the p-type silicon core layer PSC is set to be in a range of, for example, 10¹⁵ cm⁻³ to 10²⁰ cm⁻³, which is a relatively low concentration. The typical value is, for example, about 10¹⁸ cm³.

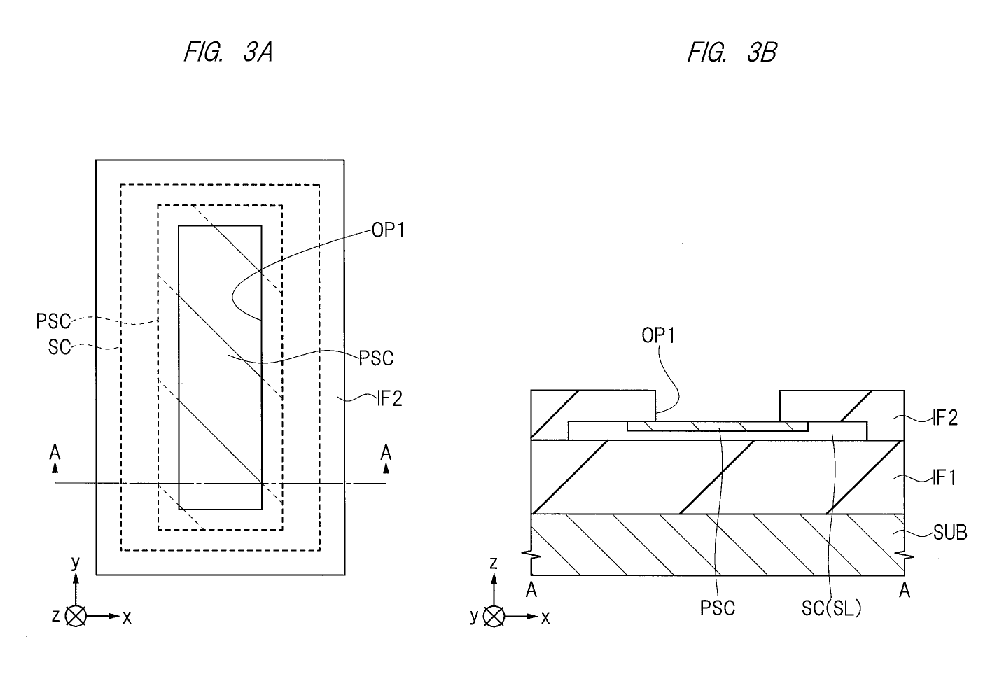

Then, as shown in FIGS. 3A and 3B, the second insulating film IF2 is formed on the first insulating film IF1 so as to cover the silicon core layer SC. The second insulating film IF2 is made of, for example, silicon oxide (SiO²) and has a thickness of, for example, about 2 μm.

Then, a resist pattern (illustration is omitted) is formed by coating the second insulating film IF2 with a photoresist, exposing the film to light, and then, performing a development process to pattern the photoresist. Subsequently, a firs opening OP1 which exposes a part of the upper surface of the p-type silicon core layer PSC is formed by processing the second insulating film IF2 by dry etching while using the resist pattern as a mask. Then, the resist pattern is removed.

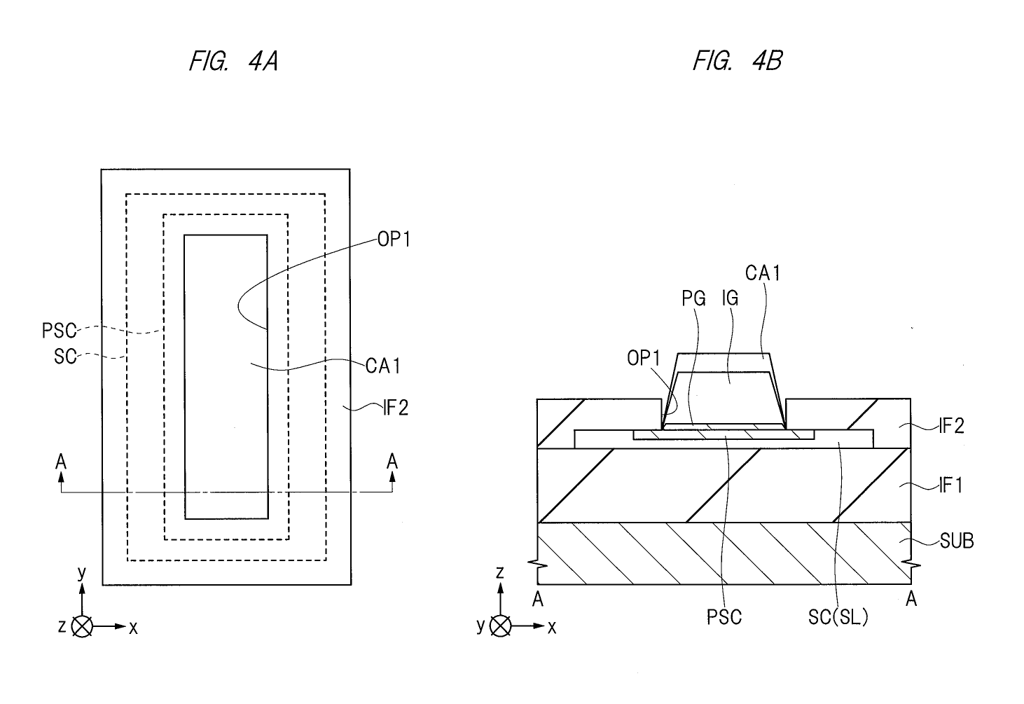

Then, as shown in FIGS. 4A and 4B, the p-type germanium layer PG introduced with the p-type impurity such an boron (B) is formed selectively on the upper surface of the p-type silicon core layer PSC exposed from the bottom of the first opening OP1. The p-type germanium layer PG is formed by an epitaxial growth method performed under, for example, a substrate temperature of 600° C. using a GeH₄ gas added with a B₂H₆ gas. A thickness of the p-type germanium layer PG is, for example, 100 nm or less.

Further, the i-type germanium layer IG is formed selectively on the exposed surface (upper surface and side surface) of the p-type germanium layer PG. The i-type germanium layer IG is formed by an epitaxial growth method performed under, for example, a substrate temperature of 600° C. using a GeH₄ gas. A thickness of the i-type germanium layer IG is, for example, about 300 nm to 20,000 nm.

Further, the first cap layer CA1 is formed selectively on the exposed surface (upper surface and side surface) of the i-type germanium layer IG. In this manner, the exposed surface (upper surface and side surface) of the i-type germanium layer IG is covered with the first cap layer CA1. The first cap layer CA1 is made of, for example, silicon (Si), and is formed by an epitaxial growth method performed under, for example, a substrate temperature of 600° C. using a disilane (Si₂H₆) gas, monosilane (SiH₄) gas, dichlorosilane (SiH₂Cl₂) gas, or others. A thickness of the first cap layer CA1 is, for example, 50 nm or less, preferably about 10 nm to 30 nm. The first cap layer CA1 can be made of silicon germanium (SiGe) instead of silicon (Si).

Here, the p-type germanium layer PG, the i-type germanium layer IG, and the first cap layer CA1 can be formed continuously in the same device by switching the gas. In this manner, the occurrence of the defect can be suppressed on the interface between the p-type silicon core layer PSC and the p-type germanium layer PG, the interface between the p-type germanium layer PG and the i-type germanium layer IG, and the interface between the i-type germanium layer IG and the first cap layer CA1. When the exposed surface (upper surface and side surface) of the i-type germanium layer IG is exposed to an oxygen atmosphere, the i-type germanium layer IG is oxidized. However, by the continuous formation of the first cap layer CA1 on the surface (upper surface and side surface) of the i-type germanium layer IG in the same device, the oxidation of the i-type germanium layer IG can be prevented.

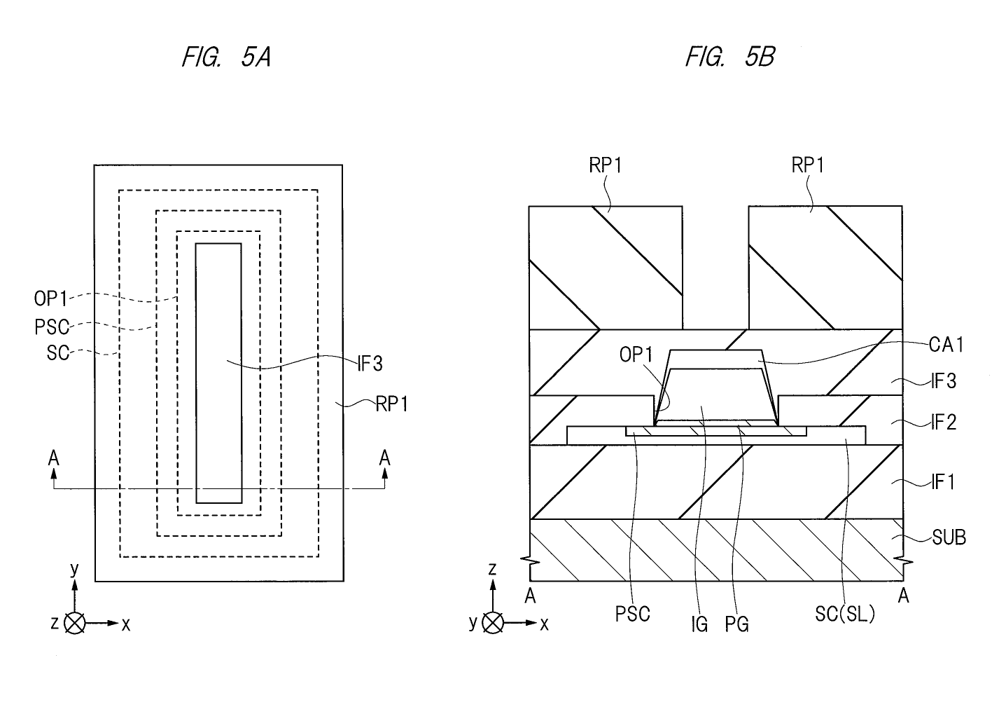

Then, as shown in FIGS. 5A and 5B, the third insulating film IF3 is formed on the first cap layer CA1 and on the second insulating film IF2. The third insulating film IF3 is made of silicon oxide (SiO₂) film formed by, for example, a plasma CVD (Chemical Vapor Deposition) method or a SACVD (Sub-Atmospheric Chemical Vapor Deposition). The third insulating film IF3 may be a TEOS oxide film formed by using TEOS (Tetra Ethyl Ortho Silicate; Si(OC₂H₅)₄) and ozone (O₃) as source gases. Even when the third insulating film IF3 made of silicon oxide (SiO₂) is formed, the oxidation of the i-type germanium layer IG can be prevented because the surface (upper surface and side surface) of the i-type germanium layer IG is covered with the first cap layer CA1.

After that, the upper surface of the third insulating film IF3 is flattened by, for example, a CMP (Chemical Mechanical Polishing) method or others.

Then, the third insulating film IF3 is coated with a photoresist, is exposed to light, and is subjected to a development process, so that the photoresist is patterned to form a resist pattern RP1.

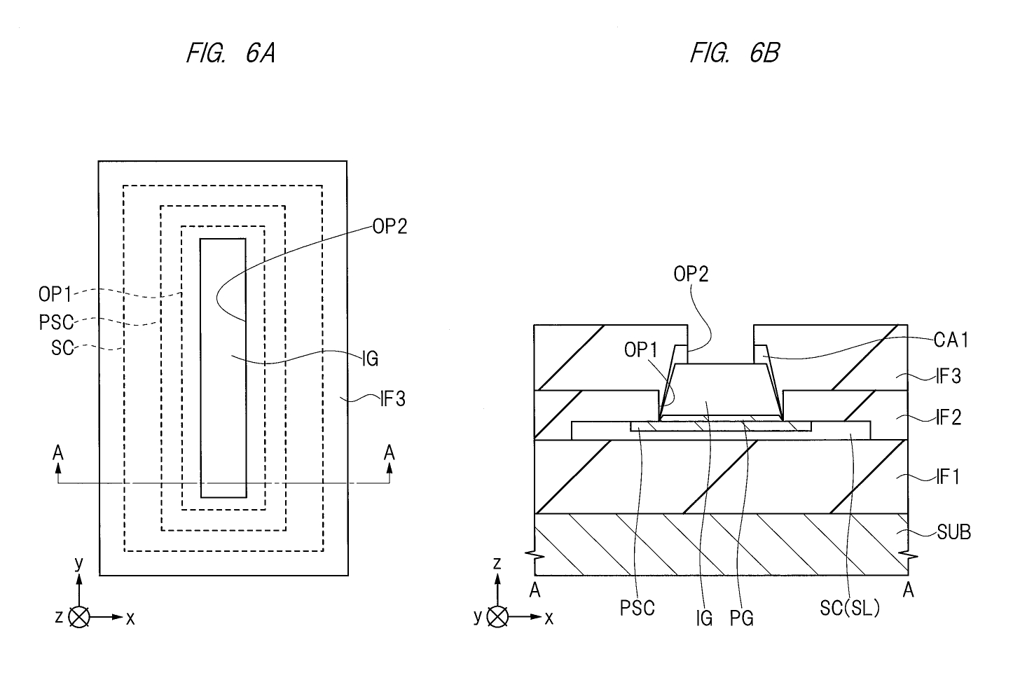

Then, as shown in FIGS. 6A and 6B, the third insulating film IF3 and the first cap layer CA1 are processed by dry etching while using the resist pattern RP1 as a mask, so that a second opening OP2 exposing a part of the upper surface of the i-type germanium layer IG is formed. Then, the resist pattern RP1 is removed.

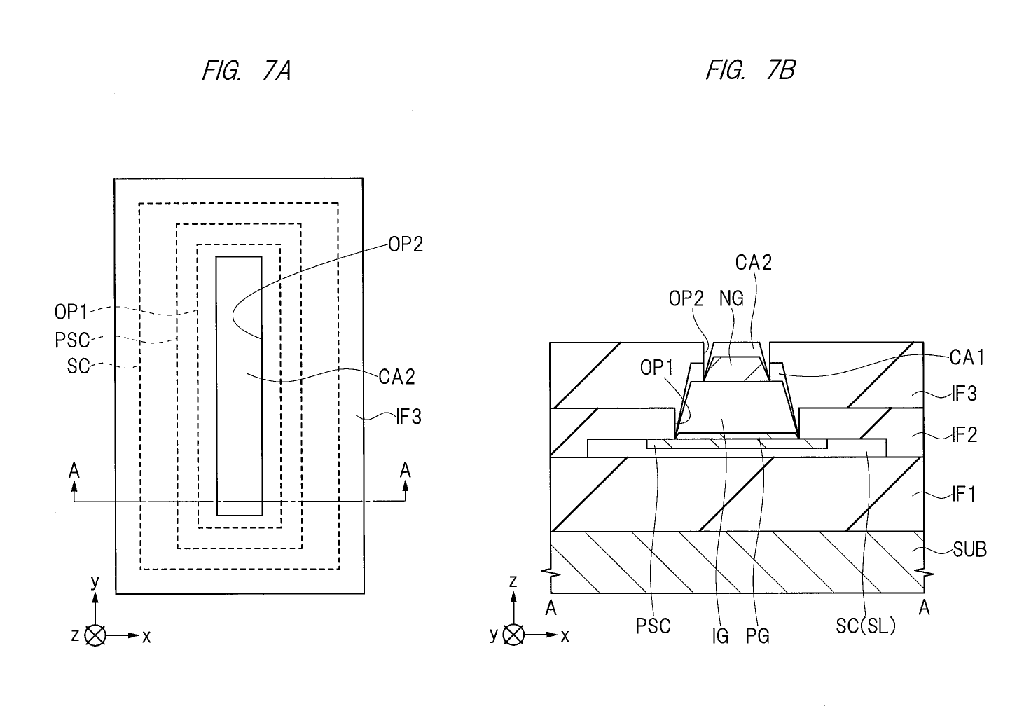

Then, as shown in FIGS. 7A and 7B, the n-type germanium layer NG introduced with the n-type impurity such an phosphorous (P) is formed selectively on the upper surface of the i-type germanium layer IG exposed from the bottom of the second opening OP2. The n-type germanium layer NG is formed by an epitaxial growth method performed under, for example, a substrate temperature of 600° C. using a GeH₄ gas added with a PH₃ gas. The n-type germanium layer NG may be formed by using a gas obtained by adding AsH₃ gas to GeH₄ gas instead of PH₃ gas. A thickness of the n-type germanium layer NG is, for example, about 100 to 200 nm.

Further, the second cap layer CA2 is formed selectively on the exposed surface (upper surface and side surface) of the n-type germanium layer NG. In this manner, the exposed surface (upper surface and side surface) of the n-type germanium layer NG is covered with the second cap layer CA2. The second cap layer CA2 is made of, for example, silicon (Si), and is formed by an epitaxial growth method performed under, for example, a substrate temperature of 600° C. using a disilane (Si₂H₆) gas, monosilane (SiH₄) gas, dichlorosilane (SiH₂Cl₂) gas, or others. A thickness of the second cap layer CA2 is, for example, 50 nm or less, preferably about 10 nm to 30 nm. The second cap layer CA1 can be made of silicon germanium (SiGe) instead of silicon (Si).

Here, the n-type germanium layer NG and the second cap layer CA2 can be formed continuously in the same device by switching the gas. In this manner, the occurrence of the defect can be suppressed on the interface between the n-type germanium layer NG and the second cap layer CA2. When the exposed surface (upper surface and side surface) of the n-type germanium layer NG is exposed to an oxygen atmosphere, the n-type germanium layer NG is oxidized. However, by the continuous formation of the second cap layer CA2 on the surface (upper surface and side surface) of the n-type germanium layer NG in the same device, the oxidation of the n-type germanium layer NG can be prevented.

The n-type germanium layer NG is formed inside the second opening portion OP2, and therefore, the n-type germanium layer NG and the p-type germanium layer PG come close to each other, so that the dope element does not mutually diffuse between these layers.

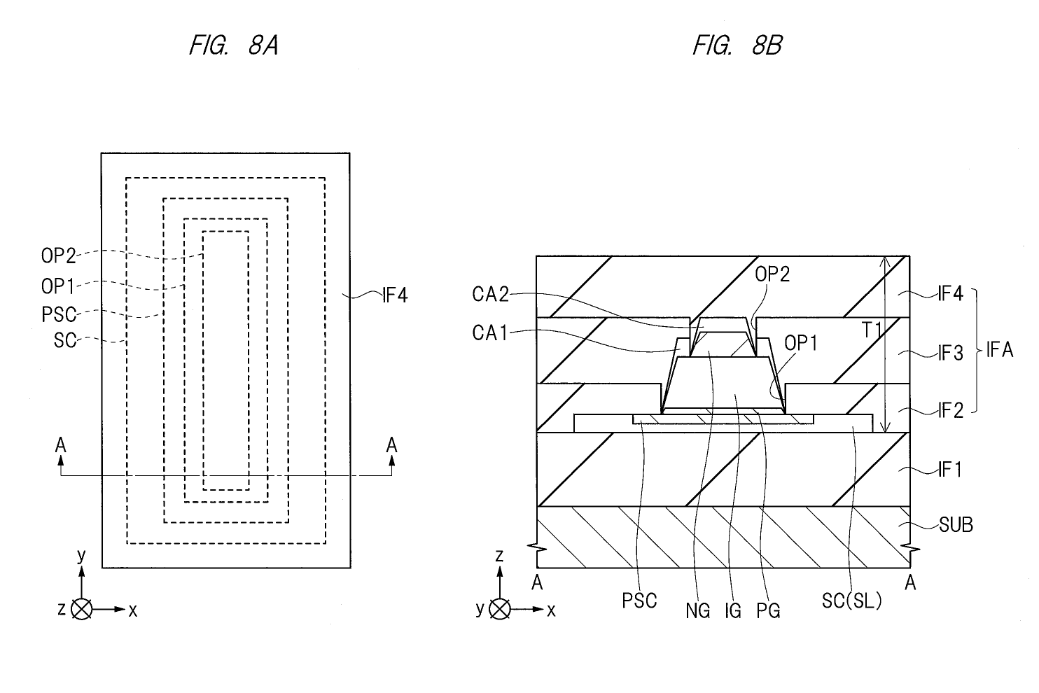

Then, as shown in FIGS. 8A and 8B, the fourth insulating film IF4 is formed on the second cap layer CA2 and on the third insulating film IF3. In this manner, an insulating film IFA formed of the second insulating film IF2, the third insulating film IF3, and the fourth insulating film IF4. The fourth insulating film IF4 is made of silicon oxide (SiO₂) film formed by, for example, a plasma CVD method. Each film thickness T1 of the second insulating film IF2, the third insulating film IF3, and the fourth insulating film IF4 is, for example, about 2 to 3 μm.

After that, the upper surface of the fourth insulating film IF4 is flattened by, for example, a CMP method or others.

Then, the fourth insulating film IF4 is coated with a photoresist, is exposed to light, and is subjected to a development process, so that the photoresist is patterned to form a resist pattern (illustration is omitted).

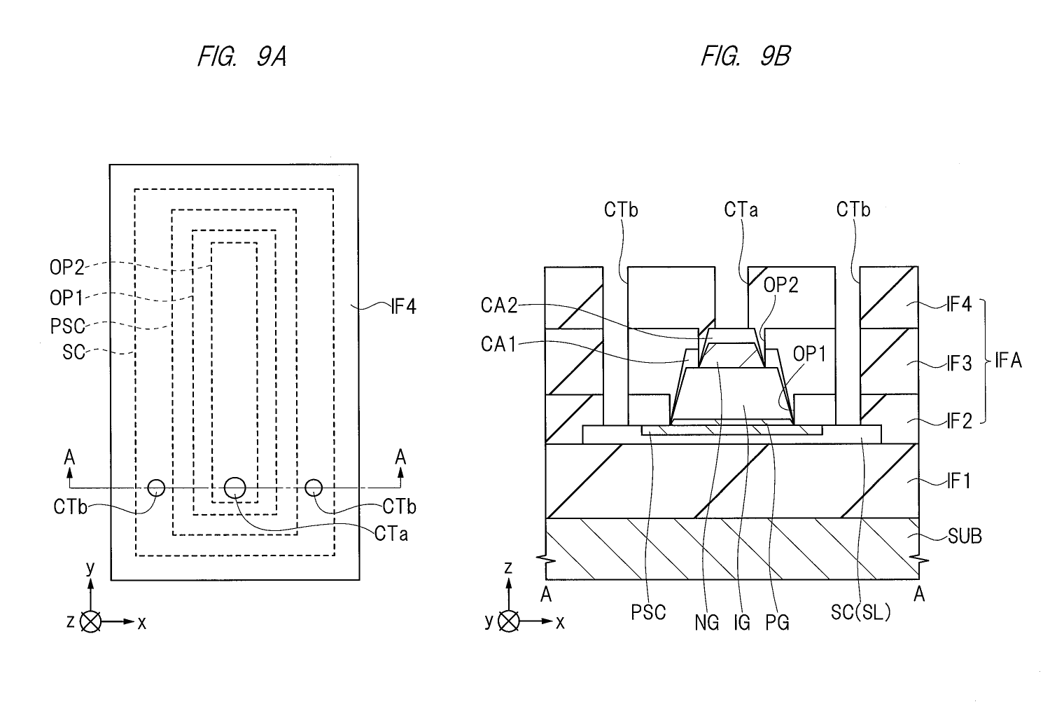

Then, as shown in FIGS. 9A and 9B, the fourth insulating film IF4, the third insulating film IF3, and the second insulating film IF2 are processed by using a dry etching method using the resist pattern as a mask to form a connection hole CTb reaching the silicon core layer SC, and at the same time, the fourth insulating film IF4 is processed by using a dry etching method to form a connection hole CTa reaching the second cap layer CA2. Here, the connection hole CTa and the connection hole CTb are formed at the same time here. However, they may be formed by different processes from each other.

Then, as shown in FIGS. 1A and 1B, a conductive film is buried inside the connection holes CTa and CTb via a barrier metal to form the plug PL having the buried conductive film as its main conductive material. The main conductive material making up the plug PL is made of, for example, aluminum (Al), tungsten (W), or others, and the barrier metal is made of, for example, titanium (Ti), titanium nitride (TiN), or others.

Then, a barrier metal, a metal film (main conductive material), and a barrier metal are sequentially stacked on the plug PL and the fourth insulating film IF4 by, for example, a sputtering method or others, so that this stacked film is processed by a dry etching method while using a resist pattern as a mask to form the first layer wiring M1. The main conductive material making up the first layer wiring M1 is made of, for example, aluminum (Al), and the barrier metal is made of, for example, tantalum (Ta), titanium (Ti), tantalum nitride (TaN), titanium nitride (TiN), or others.

After that, a higher layer wiring is formed. A protective film is formed on the uppermost layer wiring, and then, the protective film is processed to expose the upper surface of the uppermost layer wiring. In this manner, the germanium optical receiver PD1 having the pin structure formed of the p-type germanium layer PG, the i-type germanium layer IG, and the n-type germanium layer NG according to the first embodiment is substantially completed.

In the method of manufacturing the germanium optical receiver PD1 according to the first embodiment, each of the p-type germanium layer PG, the i-type germanium layer IG, and the n-type germanium layer NG is formed on the main surface of the p-type silicon core layer PSC by the epitaxial growth method, and the ion implantation method is not used for injecting an impurity into the p-type germanium layer PG and into the n-type germanium layer NG. Therefore, it is difficult to damage the interface between the p-type silicon core layer PSC and the p-type germanium layer PG, the interface between the p-type germanium layer PG and the i-type germanium layer IG, and the interface between the i-type germanium layer IG and the n-type germanium layer NG, and therefore, the occurrence of the defect in each interface can be suppressed.

The first cap layer CA1 is formed continuously on the surface (upper surface and side surface) of the i-type germanium layer IG in the same device, and the second cap layer CA2 is formed continuously on the surface (upper surface and side surface) of the n-type germanium layer NG in the same device, and therefore, the i-type germanium layer IG and n-type germanium layer NG are not exposed to an oxygen atmosphere. The surface (upper surface and side surface) of the i-type germanium layer IG is covered with the first cap layer CA1, and then, the third insulating film IF3 made of silicon oxide (SiO₂) is formed, and therefore, the i-type germanium layer IG is not exposed to the oxygen atmosphere at the formation of the third insulating film IF3. Similarly, the surface (upper surface and side surface) of the n-type germanium layer NG is covered with the second cap layer CA2, and then, the fourth insulating film IF4 made of silicon oxide (SiO₂) is formed, and therefore, the n-type germanium layer NG is not exposed to the oxygen atmosphere at the formation of the fourth insulating film IF4. In this manner, oxidation of the i-type germanium layer IG and n-type germanium layer NG can be prevented.

Further, the n-type germanium layer NG is formed inside the second opening OP2 formed on the first cap layer CA1 and the third insulating film IF3. Therefore, by the epitaxial growth method, the n-type germanium layer NG is formed on the upper surface of the i-type germanium layer IG and is not formed on the side surface of the i-type germanium layer IG. In this manner, the n-type germanium layer NG and the p-type germanium layer PG approach each other to allow the doping elements to mutually diffuse between the layers, and therefore, the deterioration of the functions of the optical receiver can be prevented.

In this manner, according to the first embodiment, each of the p-type germanium layer PG, the non-doped i-type germanium layer IG, and the n-type germanium layer NG is formed on the p-type silicon core layer PSC by the epitaxial growth method, so that the dark current in the germanium optical receiver PD1 can be reduced. Also, the deterioration of the functions of the optical receiver PD1 can be prevented.

### Second Embodiment

<Structure of Semiconductor Device>

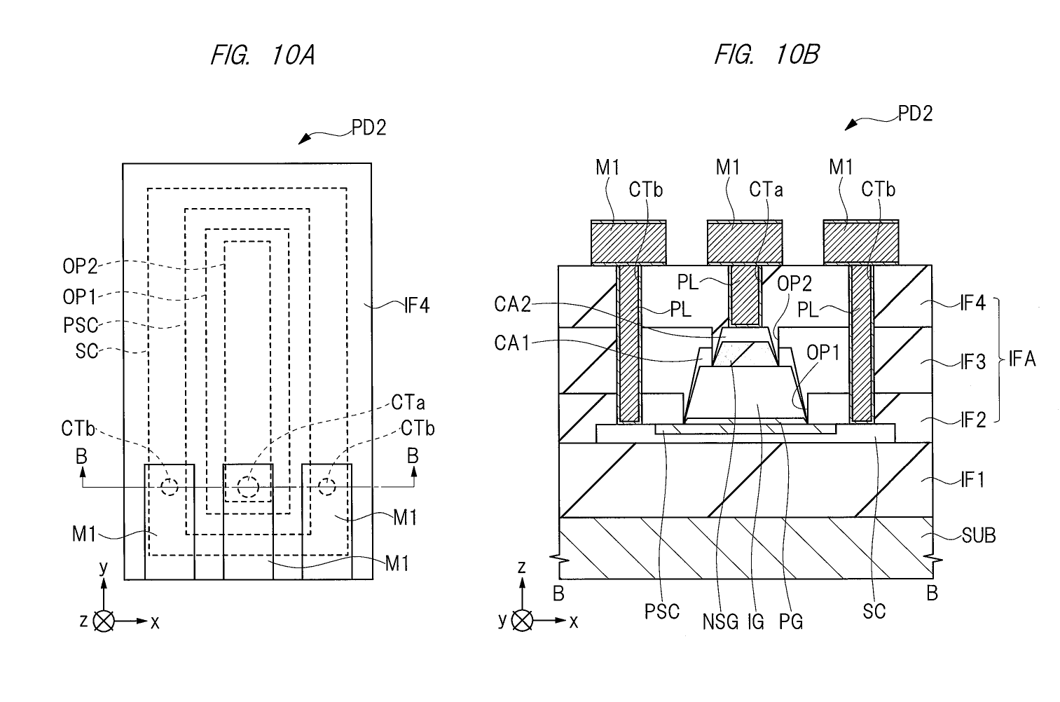

A structure of a germanium optical receiver according to a second embodiment will be described with reference to FIG. 10. FIGS. 10A and 10B are a top view of a principle part of the germanium optical receiver according to the second embodiment, and a cross-sectional view of the principle part of the germanium optical receiver (i.e., cross-sectional view taken along a line B-B of FIG. 10A), respectively.

The germanium optical receiver PD2 according to the second embodiment is different from the above-described germanium optical receiver PD1 of the first embodiment in that, in the germanium optical receiver PD2, the n-type germanium layer NG making up a part of the germanium optical receiver PD1 is formed of an n-type silicon germanium layer NSG.

That is, as shown in FIG. 10, in the germanium optical receiver PD2, a vertical pin structure is formed of the p-type germanium layer PG, the i-type germanium layer IG, and the n-type silicon germanium layer NSG, which are formed on the p-type silicon core layer PSC, and the second cap layer CA2 made of silicon. In this structure, the i-type germanium layer IG, the n-type silicon germanium layer NSG, and the second cap layer CA2 become gradually smaller in this order in the covalent bonding radius, and therefore, the occurrence of the defect on the interface between the i-type germanium layer IG and the n-type silicon germanium layer NSG and on the interface between the n-type silicon germanium layer NSG and the second cap layer CA2 is suppressed, so that the increase in dark current can be suppressed.

The germanium concentration of the n-type silicon germanium layer NSG may be uniform. Alternatively, the germanium concentration may be set so that the germanium concentration in the n-type silicon germanium layer NSG is gradually decreased from the i-type germanium layer IG toward the second cap layer CA2. Regarding the silicon, the silicon concentration may be set so that the silicon concentration in the n-type silicon germanium layer NSG is gradually increased from the i-type germanium layer IG toward the second cap layer CA2. In this manner, the covalent bonding radius in the n-type silicon germanium layer NSG gradually changes, and therefore, the increase in dark current can be further suppressed.

Such a composition gradation of germanium or silicon can be controlled easily by adjusting various gases injected into the epitaxial device and their flow rates when the n-type silicon germanium layer NSG is formed by the epitaxial growth method. Therefore, the desired composition gradation of germanium or silicon can be obtained easily.

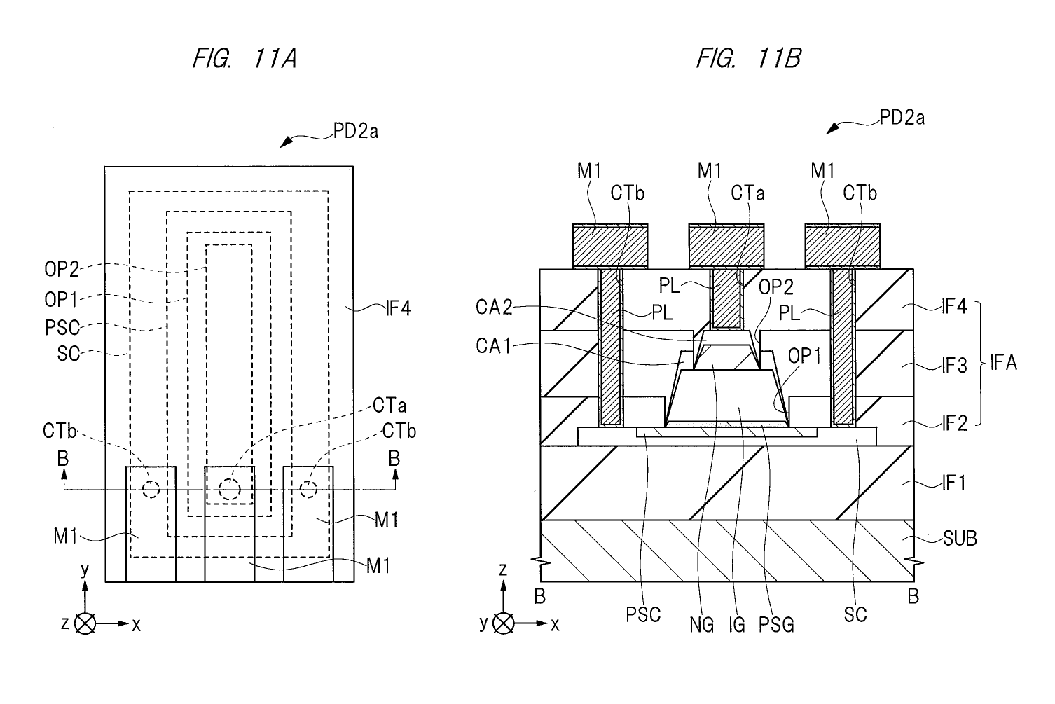

A structure of a modification example of the germanium optical receiver according to the second embodiment will be described with reference to FIG. 11. FIGS. 11A and 11B are a top view of a principle part of the modification example of the germanium optical receiver according to the second embodiment, and a cross-sectional view of the principle part of the modification of the germanium optical receiver (i.e., cross-sectional view taken along a line B-B of FIG. 11A).

As shown in FIG. 11, in the germanium optical receiver PD2a, a vertical pin structure is formed of the p-type silicon germanium layer PSG, the i-type germanium layer IG, and the n-type germanium layer NG, which are formed on the p-type silicon core layer PSC, and the second cap layer CA2 made of silicon. In this structure, the i-type germanium layer IG, the p-type silicon germanium layer PSG, and the p-type silicon core layer become gradually smaller in this order in the covalent bonding radius, and therefore, the occurrence of the defect on the interface between the i-type germanium layer IG and the p-type silicon germanium layer PSG and on the interface between the p-type silicon germanium layer PSG and the p-type silicon core layer PSC is suppressed, so that the increase in dark current can be suppressed.

The germanium concentration of the p-type silicon germanium layer PSG may be uniform. Alternatively, the germanium concentration may be set so that the germanium concentration in the p-type silicon germanium layer PSG is gradually decreased from the i-type germanium layer IG toward the p-type silicon core layer PSC. Regarding the silicon, the silicon concentration maybe set so that the silicon concentration in the p-type silicon germanium layer PSC is gradually increased from the i-type germanium layer IG toward the p-type silicon germanium layer PSG. In this manner, the covalent bonding radius in the p-type silicon germanium layer PSG gradually changes, and therefore, the increase in dark current can be further suppressed.

In this manner, according to the second embodiment, by using the n-type silicon germanium layer NSG or p-type silicon germanium layer PSG, the dark current in the germanium optical receiver PD2a can be decreased as similar to the above-described first embodiment. Also, the deterioration of the functions of the germanium optical receiver PD2a is prevented as well.

Here, the germanium optical receiver whose plane pattern is rectangular has been described. However, the germanium optical receiver may be a germanium optical receiver having a circular pattern.

### Third Embodiment

<Structure of Semiconductor Device>

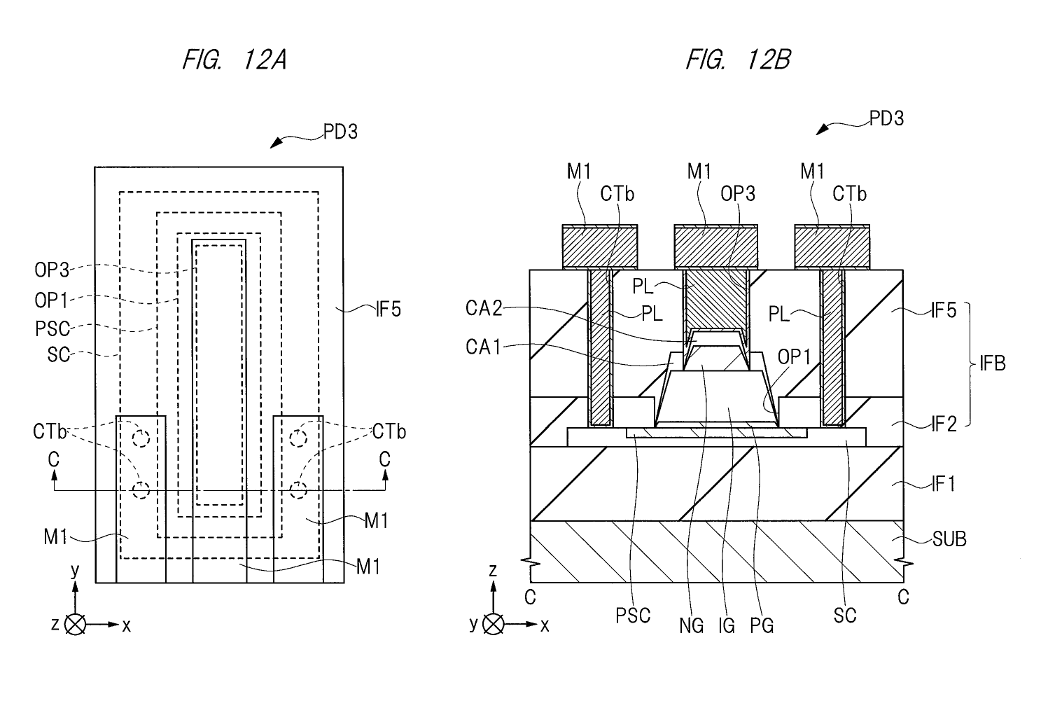

A structure of a germanium optical receiver according to a third embodiment will be described with reference to FIG. 12. FIGS. 12A and 12B are a top view of a principle part of the germanium optical receiver according to the third embodiment, and a cross-sectional view of the principle part of the germanium optical receiver (i.e., cross-sectional view taken along a line C-C of FIG. 12A), respectively.

As similar to the above-described germanium optical receiver PD1 according to the first embodiment, the germanium optical receiver PD3 according to the third embodiment is formed of the p-type germanium layer PG doped with the p-type impurity, the non-doped i-type germanium layer IG, and the n-type germanium layer NG doped with the n-type impurity, which are sequentially stacked on the upper surface of the p-type silicon core layer PSC formed on the silicon core layer SC. Further, the first cap layer CA1 made of silicon (Si) is formed so as to cover the side surface of the i-type germanium layer IG, and the second cap layer CA2 made of silicon (Si) is formed so as to cover the upper surface and side surface of the n-type germanium layer NG.

However, in the germanium optical receiver PD3 according to the third embodiment, the insulating film (referred also to as upper clad layer) IFB covering the periphery of the first and second cap layers CA1 and CA2 is formed of the second insulating film IF2 and a fifth insulating film IF5, each of which is made of silicon oxide (SiO₂). A thickness of the insulating film IFB is, for example, about 2 μm to 3 μm. In addition, the opening used for forming the n-type germanium layer NG and the second cap layer CA2 and the opening used for forming the plug PL electrically connected to the second cap layer CA2 are commonly used.

That is, in the above-described first embodiment, as shown in FIG. 1B, the n-type germanium layer NG and the second cap layer CA2 are formed inside the opening (second opening OP2) formed on the third insulating film IF3, and the plug PL is formed inside the opening (connection hole CTa) formed on the fourth insulating film IF4. On the other hand, in the third embodiment, as shown in FIG. 12B, the n-type germanium layer NG and the second cap layer CA2 are formed inside an opening (third opening OP3) formed on the fifth insulating film IF5, and besides, the plug PL is formed therein. In the germanium optical receiver PD3 according to the third embodiment in this manner, the number of the manufacturing processes can be smaller than that of the above-described germanium optical receiver PD1 according to the first embodiment.

Also in the third embodiment, the n-type silicon germanium layer NSG or the p-type silicon germanium layer PSG can be used as similar to the above-described second embodiment.

In the above-described first embodiment, as shown in FIG. 1A, note that the first layer wiring M1 is formed so that the first layer wiring M1 overlaps a partial region of the second opening OP2 of the germanium optical receiver PD1 when seen in a plan view. On the other hand, in the third embodiment, as shown in FIG. 12A, the first layer wiring M1 is formed so that the first layer wiring M1 overlaps entire region of the third opening OP3 of the germanium optical receiver PD3 when seen in a plan view. Therefore, in the germanium optical receiver PD3 according to the third embodiment, light irradiation is required from the semiconductor substrate SUB side toward the germanium optical receiver PD3.

Here, the germanium optical receiver whose plane pattern is rectangular has been described. However, the germanium optical receiver may be a germanium optical receiver having a circular pattern.

<Method of Manufacturing Semiconductor Device>

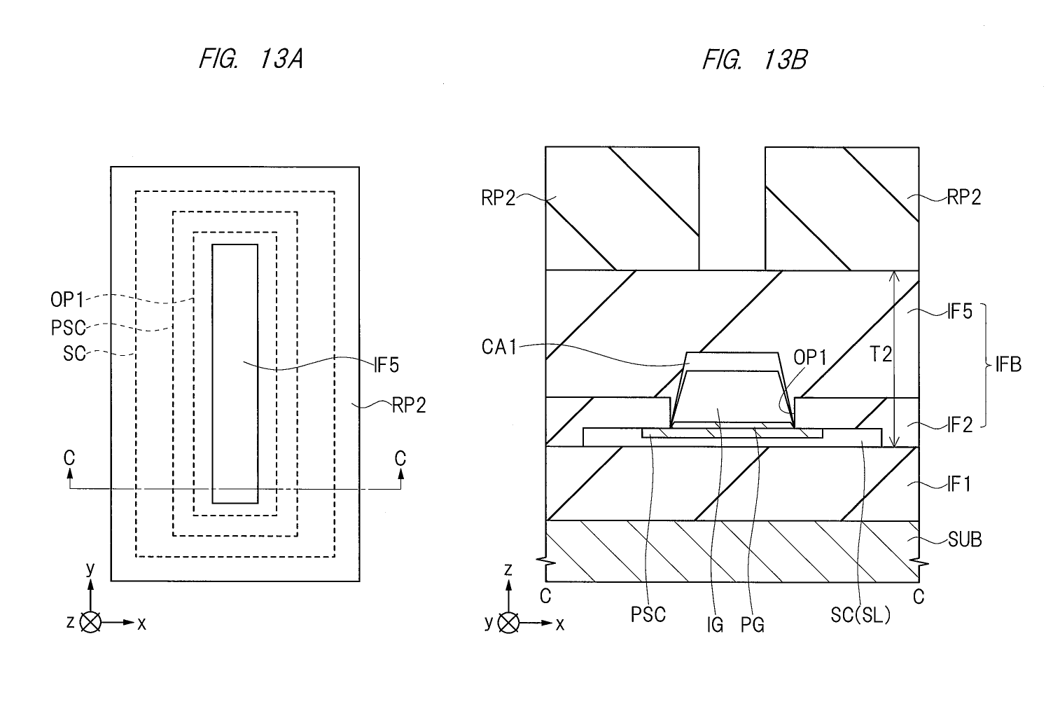

A method of manufacturing the germanium optical receiver according to the third embodiment will be described in order of processes, with reference to FIGS. 13 to 16. In FIGS. 13 to 16, each of FIGS. 13A to 16A shows a top view of a principle part of the germanium optical receiver during manufacturing processes of the third embodiment, and each of FIGS. 13B to 16B shows a cross-sectional view of the principle part of the germanium optical receiver (i.e., cross-sectional view taken along a line C-C of each of FIGS. 13A to 16A) during the manufacturing processes.

First, as similar to the above-described first embodiment, the silicon core layer SC, the p-type silicon core layer PSC, the p-type germanium layer PG, the i-type germanium layer IG, and the first cap layer CA1 are sequentially formed (see, FIGS. 2, 3, and, 4). The manufacturing process up to this point is the same as the manufacturing process of the first embodiment, and therefore, will be omitted.

Then, as shown in FIGS. 13A and 13B, the fifth insulating film IF5 is formed on the first cap layer CA1 and on the second insulating film IF2. In this manner, the insulating film IFB formed of the second insulating film IF2 and the fifth insulating film IF5 is formed. The fifth insulating film IF5 is made of silicon oxide (SiO₂) and formed by, for example, a plasma CVD method or a SACVD method. The fifth insulating film IF5 may be a TEOS oxide film formed by using TEOS and ozone as source gases.

After that, the upper surface of the fifth insulating film IF5 is flattened by, for example, a CMP method or others. A thickness of the fifth insulating film IF5 is almost the same as the stacking thickness of the third insulating film IF3 and the fourth insulating film IF4 described in the above-described first embodiment, and a stacking thickness T2 of the second insulating film IF2 and the fifth insulating film IF5 is, for example, about 2 to 3 m

Then, the fifth insulating film IF5 is coated with a photoresist, is exposed to light, and is subjected to a development process, so that the photoresist is patterned to form a resist pattern RP2.

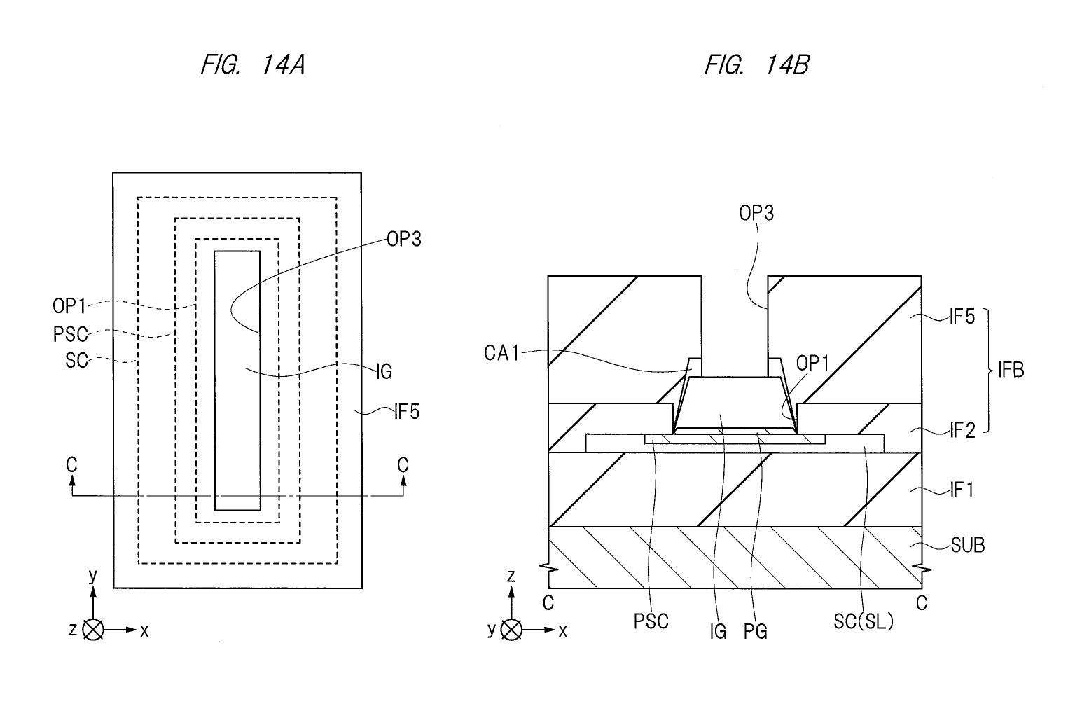

Then, as shown in FIGS. 14A and 14B, the fifth insulating film IF5 and the first cap layer CA1 are processed by using a dry etching method using the resist pattern RP2 as a mask to form the third opening OP3 exposing a part of the upper surface of the i-type germanium layer IG. After that, the resist pattern RP2 is removed.

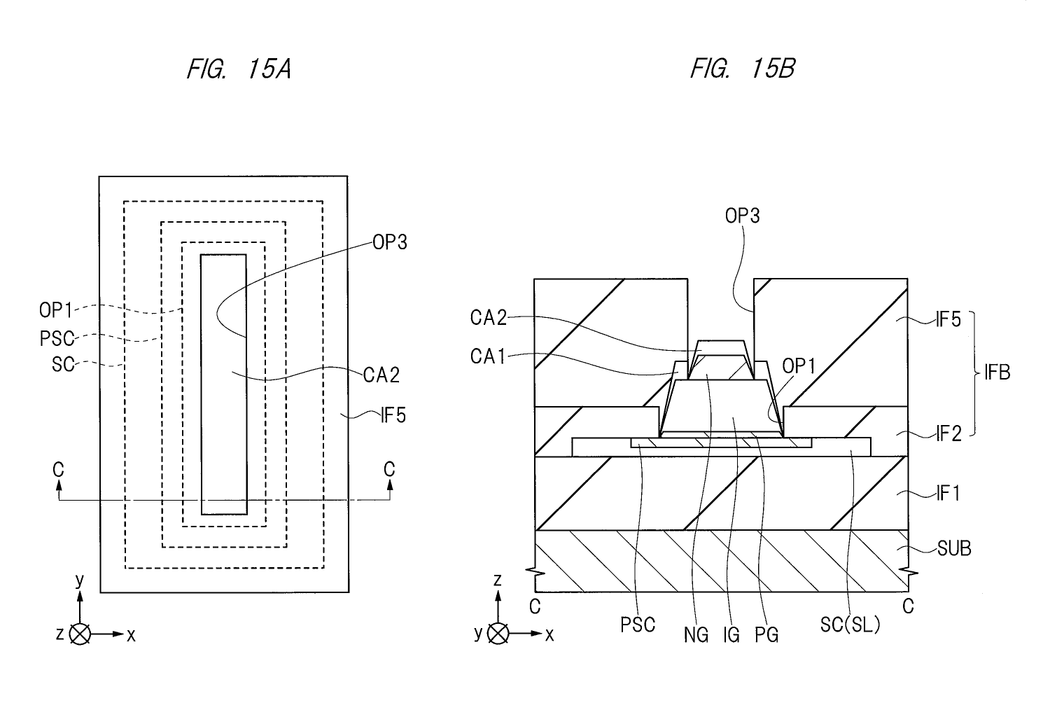

Then, as shown in FIGS. 15A and 15B, as similar to the above-described first embodiment, the n-type germanium layer NG and the second cap layer CA2 are selectively and sequentially formed on the upper surface of the i-type germanium layer IG that is exposed from the bottom of the third opening OP3.

Then, the fifth insulating film IF5 is coated with a photoresist, is exposed to light, and is subjected to a development process, so that the photoresist is patterned to form a resist pattern (illustration is omitted).

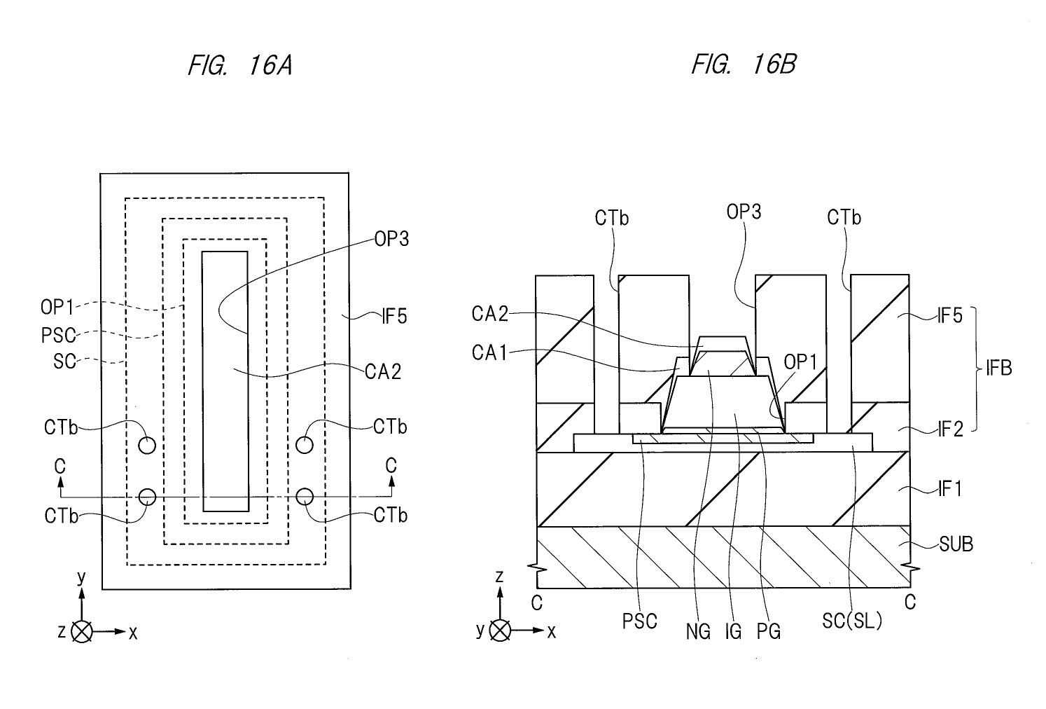

Then, as shown in FIGS. 16A and 16B, the fifth insulating film IF5 and the second insulating film IF2 are processed by using a dry etching method using the resist pattern as a mask to form the connection hole CTb reaching the silicon core layer SC.

Then, as shown in FIGS. 12A and 12B, as similar to the above-described first embodiment, the plug PL is formed via a barrier metal inside the third opening OP3 and the connection hole CTb, and the first layer wiring M1 electrically connected to the plug PL is formed.

After that, a higher layer wiring is formed. A protective film is formed on the uppermost layer wiring, and then, the protective film is processed to expose the upper surface of the uppermost layer wiring. In this manner, the germanium optical receiver PD3 having the pin structure formed of the p-type germanium layer PG, the i-type germanium layer IG, and the n-type germanium layer NG according to the third embodiment is substantially completed.

In this manner, according to the third embodiment, the manufacturing process can be shorter and the manufacturing cost can be smaller than those of the above-described first embodiment.

In the foregoing, the invention made by the present inventors has been concretely described based on the embodiments. However, it is needless to say that the present invention is not limited to the foregoing embodiments and various modifications and alterations can be made within the scope of the present invention.

What is claimed is:

1. A semiconductor device comprising:
a silicon core layer;
a first germanium layer of a first conductive type formed on an upper surface of the silicon core layer;
a non-doped second germanium layer formed on an upper surface of the first germanium layer;
a third germanium layer of a second conductive type different from the first conductive type, the third germanium layer being formed on an upper surface of the second germanium layer; and
a cap layer formed on an upper surface of the third germanium layer,
wherein the third germanium layer is doped with an element having a covalent bonding radius smaller than a covalent bonding radius of germanium.

2. The semiconductor device according to claim 1,
wherein the cap layer is made of silicon or silicon germanium.

3. The semiconductor device according to claim 1,
wherein silicon is contained in the third germanium layer, a silicon concentration on a second germanium layer side of the third germanium layer is lower than a silicon concentration on a cap layer side of third germanium layer.

4. The semiconductor device according to claim 1,
wherein a width of an upper surface of the second germanium layer in a first direction is larger than a width of a lower surface of the third germanium layer in the first direction.

5. The semiconductor device according to claim 1,
wherein a thickness of the cap layer on an upper surface of the third germanium layer is 10 nm or more and 50 nm or less.

6. The semiconductor device according to claim 1,
wherein the element is phosphorus, arsenic, or boron.

7. A method of manufacturing a semiconductor device comprising the steps of:
(a) forming a silicon core layer on an upper surface of a first insulating film;
(b) forming a first germanium layer doped with an impurity of a first conductive type, on an upper surface of the silicon core layer;
(c) forming a non-doped second germanium layer on an upper surface of the first germanium layer;
(d) forming a first cap layer on an upper surface and a side surface of the second germanium layer;
(e) forming a second insulating film so as to cover the first cap layer;
(f) forming an opening reaching the second germanium layer by processing the first cap layer on the upper surface of the second germanium layer and the second insulating film;
(g) forming a third germanium layer doped with an impurity of a second conductive type different from the first conductive type, on the upper surface of the second germanium layer that is exposed from a bottom of the opening;
(h) forming a second cap layer on an upper surface and a side surface of the third germanium layer;
(i) forming a third insulating film so as to cover the second cap layer;
(j) forming a connection reaching the second cap layer by processing the third insulating film on the upper surface of the second cap layer; and
(k) forming a conductive material inside the connection,
wherein the first germanium layer, the second germanium layer, and the first cap layer are sequentially formed in the same device by an epitaxial growth method, and
the third germanium layer and the second cap layer are sequentially formed in the same device by the epitaxial growth method.

8. The method of manufacturing the semiconductor device according to claim 7,
wherein, in the step of (g), a covalent bonding radius of an impurity element introduced into the third germanium layer is smaller than a covalent bonding radius of germanium.

9. The method of manufacturing the semiconductor device according to claim 7,
wherein, in the step of (g), the third germanium layer is formed by using a gas including a first gas containing germanium and a second gas containing silicon while gradually increasing a ratio of the second gas to the first gas.

10. The method of manufacturing the semiconductor device according to claim 7,
wherein each of the first cap layer and the second cap layer is made of silicon or silicon germanium.

11. The method of manufacturing the semiconductor device according to claim 7,
wherein a thickness of the second cap layer on an upper surface of the third germanium layer is 10 nm or more and 50 nm or less.

12. A method of manufacturing a semiconductor device comprising the steps of:
(a) forming a silicon core layer on an upper surface of a first insulating film;
(b) forming a first germanium layer doped with an impurity of a first conductive type, on an upper surface of the silicon core layer;
(c) forming a non-doped second germanium layer on an upper surface of the first germanium layer;
(d) forming a first cap layer on an upper surface and a side surface of the second germanium layer;
(e) forming a second insulating film so as to cover the first cap layer;
(f) forming an opening reaching the second germanium layer by processing the first cap layer on the upper surface of the second germanium layer and the second insulating film;
(g) forming a third germanium layer doped with an impurity of a second conductive type different from the first conductive type, on the upper surface of the second germanium layer that is exposed from a bottom of the opening;
(h) forming a second cap layer made of silicon on an upper surface and a side surface of the third germanium layer; and
(i) forming a conductive material inside the opening,
wherein the first germanium layer, the second germanium layer, and the first cap layer are sequentially formed in the same device by an epitaxial growth method, and
the third germanium layer and the second cap layer are sequentially formed in the same device by the epitaxial growth method.

13. The method of manufacturing the semiconductor device according to claim 12,
wherein, in the step of (g), a covalent bonding radius of an impurity element introduced into the third germanium layer is smaller than a covalent bonding radius of germanium.

14. The method of manufacturing the semiconductor device according to claim 12,
wherein, in the step of (g), the third germanium layer is formed by using a gas including a first gas containing germanium and a second gas containing silicon while gradually increasing a ratio of the second gas to the first gas.

15. The method of manufacturing the semiconductor device according to claim 12,
wherein each of the first cap layer and the second cap layer is made of silicon or silicon germanium.

16. The method of manufacturing the semiconductor device according to claim 12,
wherein a thickness of the second cap layer on an upper surface of the third germanium layer is 10 nm or more and 50 nm or less.
